(19) United States
(12) Patent Application Publication
(10) Pub. No.: US 2023/0120700 A1
(43) Pub. Date: Apr. 20, 2023

(54) COOLING SYSTEM

(71) Applicant: ZF Friedrichshafen AG, Friedrichshafen (DE)

(72) Inventors: Danny Grusser, Tettnang (DE); Paul Schnebli, Ravensburg (DE); Patrick Stapf, Wangen (DE)

(73) Assignee: ZF Friedrichshafen AG, Friedrichshafen (DE)

(21) Appl. No.: 17/907,216

(22) PCT Filed: Mar. 10, 2021
(86) PCT No.: PCT/EP2021/056004

§ 371 Date: Sep. 23, 2022

(30) Foreign Application Priority Data
Mar. 25, 2020 (DE) 10 2020 203 884.8

(51) Int. Cl. H05K 7/20

(52) U.S. Cl. CPC H05K 7/20872; H05K 7/205

(57) ABSTRACT

A cooling system comprises a heat sink that bears on an electronic component (120) on a printed circuit board, and a cooling channel for a coolant. The cooling channel has a cavity for the heat sink, and the heat sink is designed to be placed in the cavity based on a distance between the component and the printed circuit board such that the printed circuit board can be placed on the cooling channel at a predetermined spacing thereto, such that the component bears on the heat sink.

### RELATED APPLICATION

This application is a filing under 35 U.S.C. § 371 of International Patent Application PCT/EP2021/056004, filed Mar. 10, 2021, and claiming priority to German Patent Application 10 2020 203 884.8, filed Mar. 25, 2020. All applications listed in this paragraph are hereby incorporated by reference in their entireties.

### TECHNICAL FIELD

The present invention relates to a cooling system. In particular, the invention relates to a cooling system for an electric module in an on-board system in a vehicle.

### BACKGROUND

A vehicle comprises a processor that controls driving functions in the vehicle, for example. The processor can transform electrical power into heat, in which the power may depend on a processing load to the processor. The heat generated by the processor can be referred to as “Thermal Design Power” (TDP), and used as the basis for the necessary size of the cooling system. An effective processor, e.g. a CPU or GPU, can have a TDP of ca. 30, 60 or more than 100 W. In particular if the processor controls a safety-relevant function in the vehicle, it is important to ensure that it remains sufficiently cooled at all times.

A cooling system with a closed cooling circuit in which a coolant circulates can be used to discharge the heat generated by the processor. The coolant is contained in a cooling channel to which a printed circuit board can be attached, onto which the processor has been soldered. The distance between the processor and the printed circuit board may vary within a predetermined range. This may result in a gap between the processor and the cooling channel, which is normally filled with a thermally conductive compound (a thermally conductive past or pad). A thermal resistance of the compound is normally relatively high, such that an optimal cooling may be prevented.

### BRIEF DESCRIPTION OF THE DRAWINGS

Certain embodiments are explained below with reference to the drawings. Therein:

FIG. 1 shows a cooling system with an electric module;

FIG. 2 shows various views of a heat sink in a cooling system;

FIG. 3 shows another view of a cooling system;

FIG. 4 shows a flow chart for a first method; and

FIG. 5 shows a flow chart for a second method.

### DETAILED DESCRIPTION

In view of the background discussed above, a fundamental object of the present invention is to provide a means for an improved thermal connection between an electronic component and a cooling channel. This object may be achieved with the invention by means of the subject matter of the independent claims. Dependent claims describe preferred embodiments.

A cooling system comprises a heat sink that is to be attached to an electronic component on a printed circuit board, and a cooling channel containing a coolant. This cooling channel has a cavity that contains the heat sink and the heat sink is designed to be placed in the cavity on the basis of a distance between the component and the printed circuit board such that the printed circuit board can be attached to the cooling channel at a predetermined spacing, such that the component bears on the heat sink.

Differences in the spacing between the component and the printed circuit board can be compensated for by the axial position of the heat sink in the cavity in the cooling channel. The spacing between the component and the printed circuit board may vary to a certain extent. If the component comprises a semiconductor in a BGA housing (“Ball Grid Array”), for example, the distance between its surface and the printed circuit board may vary within a range of ± 0.2 mm. The heat sink can be placed in the cavity such that its position varies within a corresponding range. Any remaining gap between the heat sink and the component can be reduced in this manner, ideally to the optimal thickness of an adhesive layer (the “bond line thickness”). The heat sink can be attached directly or indirectly to the component by means of a thermally conductive compound. The conductive compound can comprise a paste or solid that can be shaped when heated.

The heat sink can be designed to be received in the cavity in a force-fitting manner. In particular, the heat sink is preferably retained on the cooling channel by means of friction. This ensures that the heat sink remains securely attached thereto, even when subjected to vibrations or impacts. This may be of particular advantage if the component is to be placed with the cooling system in a vehicle. The frictional connection can be designed to accommodate a specific load requirement. By way of example, a lateral tension between the heat sink and the cooling channel may be great enough to securely retain it on the cooling channel at accelerations of multiple g-forces. The necessary lateral tension can be determined as a function of the mass of the heat sink.

The heat sink can be designed to be snapped in place in the cavity. The heat sink may be slightly larger than the cavity for this, such that a predetermined lateral tension is obtained when it is snapped in place. The heat sink can be attached to the cooling channel by a press fit or force fitting connection. The heat sink can also be attached to the cooling channel by means of temperature differential method. In a first variation, the cooling channel can be heated prior to assembly, such that the cavity is enlarged before the heat sink, which has not been heated, is placed therein. This can be referred to as a shrinking process. In a second variation, the heat sink can be cooled prior to installation in the cooling channel, which has not been cooled. This can be referred to as a thermal expansion, contraction or heat-shrinking process. These approaches can also be combined. All of these variations can enable a secure connection between the components in a precisely predetermined position after thermal equilibrium has been obtained.

The heat sink preferably has an outer end that bears on the electronic component, and an inner end that around which the coolant in the cooling channel circulates. The heat sink is preferably made of a material with a high thermal conductivity, in particular a metal such as aluminum, magnesium, copper, or silver.

The heat sink is preferably connected in a fluid-tight manner to the cooling channel. Any overflow of coolant along the surface where the heat sink bears on the cooling channel can be prevented, or at least reduced to an acceptable extent, by this. In a preferred embodiment, a seal is placed between the heat sink and the cooling channel. This seal preferably encompasses the heat sink entirely. The seal be accommodated in a space formed in the heat sink or in the cooling channel. This space can comprise a groove in an axial region lying between the inner and outer ends of the heat sink when the heat sink is placed in the cooling channel. The heat sink and the cavity can each have a circular cross section. The groove preferably forms an annular groove.

The seal can be an O-ring. The seal can be formed by an appropriate material, comprising nitrile rubber (also known as acrylonitrile butadiene rubber, nitrile butadiene rubber or NBR), for example. The O-ring can be a standard component, e.g. EPDM-70. This exhibits good properties in glycol-water mixtures. In another embodiment, a shaft seal can be used. This shaft seal is not normally placed in an annular groove, but instead in a recess in the cooling channel that opens toward the inside.

When the cooling system is installed, such that the heat sink is placed in the cavity in the cooling channel, the position of the heat sink can be labelled. This label can indicate the axial position of the heat sink, e.g. in millimeters, in relation to a predefined reference surface. In particular, the label can indicate the height of the heat sink with respect to the cooling channel. In another embodiment, the labelling can be indirect, i.e. contained in a table. The table can be generated by the manufacturer of the cooling system, e.g. in the form of a data base. A clear identifier for the cooling system is preferably attached to the cooling system. This identifier can be used as a key to make entries in the table, in which the entries indicate the axial position of the heat sink. The position of the heat sink can therefore be determined without making any measurements.

Optionally, a label can be placed in a corresponding manner on an electric module that comprises a printed circuit board and an electronic component attached thereto, which indicates the distance between the component and the heat sink. A pairing of a module and a mechanically or thermally compatible cooling system can thus be better determined in this manner.

The cooling system and the module are also preferably designed to be attached to one another at a predefined spacing. The cooling channel and printed circuit board can each have bearing surfaces for this.

A heat sink comprises and outer end and an inner end. The outer end is designed to bear on an electronic component attached to a printed circuit board, and the inner end is designed such that coolant in a cooling channel circulates around it. The heat sink is placed in a cavity in the cooling channel, based on a distance between the component and the printed circuit board, such that the printed circuit board can be attached to the cooling channel at a predefined spacing thereto. The heat sink can preferably be used in the construction of the cooling system described herein.

Numerous projections can be formed on the inner end of the heat sink, which are parallel to one another in one embodiment. The projections can be cylindrical, for example, and extend axially in relation to the heat sink, in the manner of cooling fingers. The coolant preferably flows laterally in relation to the projections in the cooling channel. In another embodiment, a meandering recess through which the coolant can flow can also be formed on the inner end. The coolant in the cooling channel can substantially flow through the meandering recess, or the meandering recess can at least facilitate the flow.

A cooling channel for a coolant contains a cavity for accommodating a heat sink. The cooling channel is attached at a specific spacing to a printed circuit board populated with an electronic component. The cooling channel is also designed to accommodate the heat sink at a spacing that is based on the distance between the component and the printed circuit board, such that the heat sink bears on the component and extends through the cavity. The cooling channel can be designed in particular to accommodate the heat sink described herein.

The present invention also comprises a first method for creating a cooling system comprised of a heat sink and a cooling channel through which a coolant flows, in which the cooling channel contains a cavity for the heat sink, the heat sink has an inner end and an outer end, the outer end is designed to bear on an electronic component attached to a printed circuit board, and a coolant in the cooling channel flows around the inner end. The method comprises steps for determining a spacing between the electronic component and the printed circuit board, and the positioning of the heat sink in the cavity in the cooling channel based on this spacing, such that the outer end of the heat sink bears on the electronic component when the printed circuit board is attached to the cooling channel at a predetermined distance thereto.

In this manner, the cooling system described herein can be individually created for or adapted specifically to a predefined module that comprises the electronic component and the printed circuit board.

A second method for creating the cooling system described herein comprises steps for creating numerous cooling channels at different distances to the heat sinks, providing a printed circuit board populated with an electronic component, and selecting one of the cooling channels on the basis of the distance between the electronic component and the printed circuit board, such that the printed circuit board can be attached to the cooling channel at a predetermined spacing thereto, such that the outer end of the heat sink bears on the electronic component.

As a result, an appropriate cooling system can be selected for a specific module. Replacing a module on a cooling system can be simplified. It is also possible to select an appropriate module for a specific cooling system. The determination of which modules are appropriate for which cooling systems can resemble the pairing of high-load gearwheels, e.g. in a primary gearing for an internal combustion engine.

gureigure 1 shows a system 100 comprising a cooling system 110 and an electric module 105. The system 100 is preferably intended for use in a vehicle, in particular a motor vehicle. The system 100 can be designed to control a vehicle function. In one embodiment, the system 100 is designed to control the vehicle longitudinally and/or laterally on the basis of a scanning of the vehicle’s environment, e.g. using a camera, radar, or lidar sensors.

The module 105 comprises a printed circuit board 115, to which an electronic component 120 is attached. The component 120 can comprise a processor, in particular, e.g. in the form of a CPU or GPU. The component 120 is normally soldered to the printed circuit board 115. It can also be attached by some other means, e.g. by means of a socket attached to the printed circuit board 115, from which the component can be unplugged. The position of the component 120 in relation to the printed circuit board 115 may vary within a specific range. Variations horizontally, i.e. parallel to the surface of the printed circuit board are not normally critical. It is also assumed that a tilting of the component 120 in relation to the printed circuit board 115 is not critical in the present case. A vertical variation in the position can be within a range of ca. ± 0.2 mm.

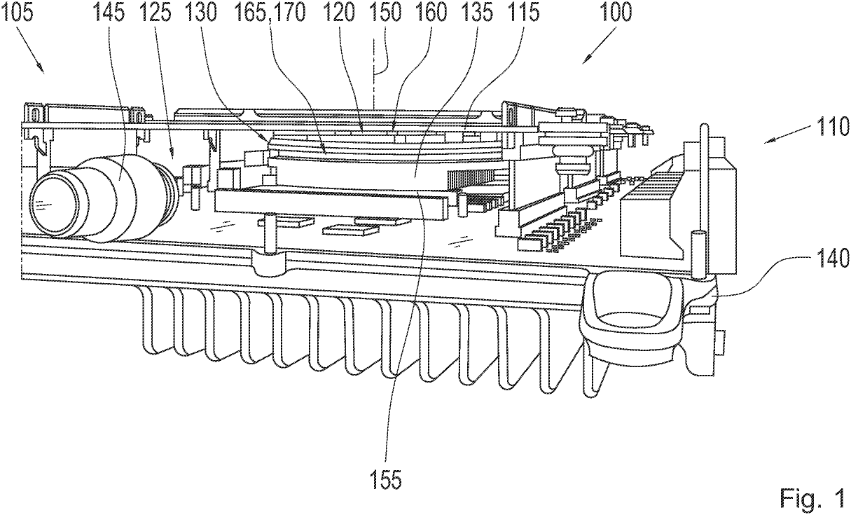

The cooling system 105 comprises a cooling channel 125 with a cavity 130 in which a heat sink 135 is placed. The cooling channel 125 can be formed by numerous elements that form a space through which a coolant can flow. The cooling channel 125 is not shown in FIG. 1. As shall be explained in greater detail below, the cooling channel 125 is designed to only allow the coolant to come in contact with a lower portion of the heat sink 135. The cooling channel 125 rests mechanically on a carrier 140, on which other components can also be installed in this example. The carrier 140 can be made of a casted light metal. Another heat sink is attached to the lower surface of the carrier 140 in FIG. 1, around which ambient air can flow.

The cooling channel 125 can be part of a closed system in which the coolant is preferably a liquid, comprising a mixture of water and glycol, for example. The cooling system 105 can be designed to allow the coolant to flow in the manner of a circulatory system around the heat sink 135, in order to absorb heat and convey it to a radiator where the heat can be discharged and then return to the heat sink. A connection can be seen in the front on the left in FIG. 1, through which the coolant in the cooling system can enter or exit.

The heat sink 135 is preferably made of a material that has a low thermal resistance, e.g. a light metal such as aluminum or magnesium. The heat sink 135 has a longitudinal axis 150 that is normally perpendicular to a boundary of the cooling channel 125. When the module 110 has been attached to the cooling system 105, the longitudinal axis 150 is preferably perpendicular to a surface of the printed circuit board 115. When referring to a radial or axial direction in the following, this is in relation to the longitudinal axis 150.

The heat sink 135 has an inner end 155, around which coolant flows, and an outer end 150 that bears on the electronic component 120, which are on opposite sides with respect to the longitudinal axis 150. The heat sink 135 passes through the cavity 130 at a region between the two ends 155 and 160. The heat sink 135 is held in place in the cooling channel by friction in this region.

The module 110 can be attached to the carrier 140, to which the cooling system 105 can be attached. In another embodiment, the module 110 can be attached directly to the cooling system 105, and in particular the cooling channel 125. The aforementioned height tolerance for the component 120 with respect to the printed circuit board 115 can result in a gap between the component 120 and the outer end 160 of the heat sink 135 attached to the cooling channel 125, which acts against an efficient heat transfer. The mechanical tolerance can be compensated for by means of a thermally conductive compound (TIM: Thermal Interface Material). Depending on the thermal resistance of the conductive compound, however, the heat sink 135 may not be optimally connected thermally to the component 120.

It is therefore proposed that the heat sink 135 be individually positioned axially in the cavity 135 for specific modules 110. By way of example, an axial position of the component 120 in relation to the printed circuit board 115 can be measured in the module 110, and the axial position of the heat sink 135 can be determined on the basis thereof.

The heat sink 135 is preferably retained mechanically on the cooling channel 125 by means of friction. To ensure that the heat sink 135 is securely attached, it can be pressed, shrink-fitted, or expansion-fitted into the cavity 130. The axial position can be set when placing the heat sink 135 on the cooling channel 135, or at a later point in time, in the calibration or adjustment steps.

A seal 165, not shown in FIG. 1, can be used to prevent coolant from overflowing from an inner surface to an outer surface of the cooling channel 125 in the region of the cavity 130. The seal 165 can form a radial seal between the heat sink 135 and the cooling channel 125 in particular. There can be a radial groove 170 for the seal 165, which can be formed in either the heat sink 135 or the material forming the cooling channel 125. The heat sink 135 and the cooling channel 125 can each have a round cross section in the region of the cavity 130. The groove 170 can form an annular groove. A typical O-ring can be used for the seal.

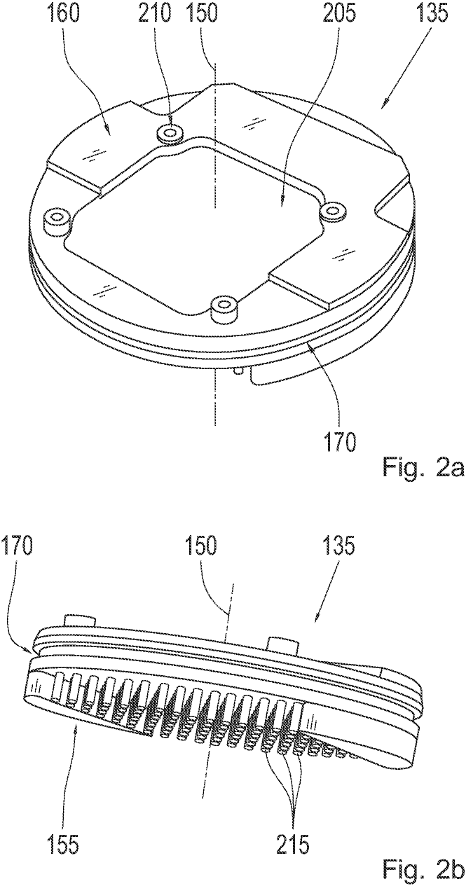

FIG. 2 shows various views of a heat sink 135 designed for use in a cooling system 105. FIG. 2a shows the outer end 160 in the foreground, while FIG. 2b gives a better view of the inner end 155.

The heat sink 135 can be basically cylindrical, or formed by such. There can be a recess 205 for electronic components 120 on the outer end 160. One or more spacers 210 can be used to ensure a minimum spacing to the printed circuit board 115. There can also be a receiver for an attachment element for the printed circuit board 115 on one of the spacers 210.

There can be a structure on the inner end that can contribute to a better heat transfer between the heat sink 135 and the coolant. The structure shown here comprises numerous projections 215 extending axially, which can also be referred to as “pin fins.” The projections 215 can have square or round cross sections. The projections 215 can be arranged uniformly in rows and columns. Every second row or column can be offset to an adjacent one. The structure can substantially fill the entire height of an inner space in the cooling channel 125 in the axial direction. The structure can be formed only in the region in which there is coolant, or the coolant flows, in the cooling channel 125. There are solid sections 220 on both sides of this cross section on the heat sink 135 in this embodiment.

In another embodiment, the structure can also comprise one or more meandering recesses formed in the material of the heat sink 135.

The groove 170 preferably has one upper and/or lower boundary surface that is perpendicular to the longitudinal axis 150. This prevents an O-ring in the groove 170 from rolling out of the groove 170 or becoming pinched therein when placing the heat sink 135 on the cooling channel 125.

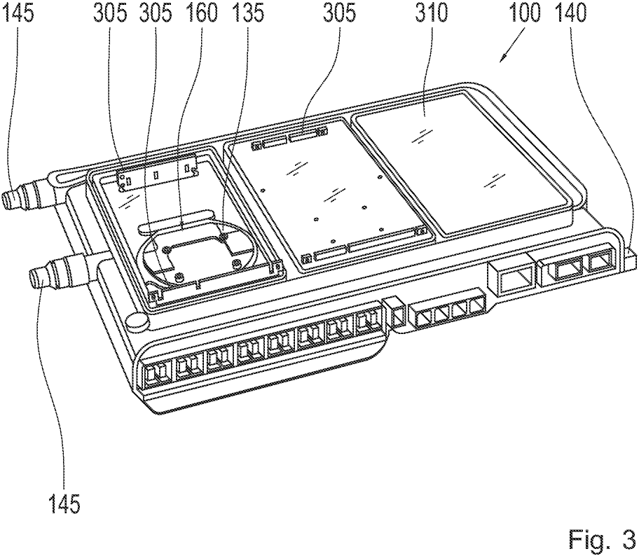

FIG. 3 shows another view of a system 100. The carrier 140 provides space for up to three electric modules 110. The space on the left of the carrier 140 has not yet been occupied by a module 110, leaving the outer end 160 of the heat sink 135 visible. Male contacts 305 for an electrical connection to a module 110 can be seen on both sides of the heat sink 135.

A module 110 has already been placed on the carrier 140 in the middle space. Upper ends of the male contacts 305 extend through corresponding holes in the module 110. The module 110 in the space on the right of the carrier 140 has a cover 310. The cover 310 can be made of a panel that preferably hermetically seals the module 110 on the carrier 140.

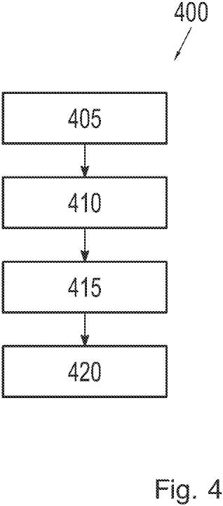

FIG. 4 shows a flow chart for a first method 400. A printed circuit board 115 can be populated with electronic components 120 in a first step 405. This results in a complete module 110. The module 110 can also be provided in its completed form with the components 120 already on the printed circuit board 115.

The height of the components 120 on the printed circuit board can be determined in step 410. The height normally refers to the distance between the printed circuit board 115 and the bearing surfaces on the components 120 for the heat sink 135. This distance is preferably determined perpendicular to a surface of the printed circuit board 115 facing the components 120. This direction is the same as the longitudinal axis 150 when the module 110 is attached to the cooling system 105.

The heat sink 135 can be positioned axially on the cooling channel 125 based on the height determined in step 415. The heat sink 135 can already be placed on the cooling channel 125 before step 415, or the placement of the heat sink 135 on the cooling channel 125 can be part of step 410. If a seal 165 is used, it can be placed in advance on the heat sink 135 or cooling channel 125. This positioning may require that an axial force be applied to the heat sink 135 that is greater than the friction between the heat sink 135 and the cooling channel 125. The positioning precision should also be higher than the tolerance for the axial position of the component 120 on the printed circuit board 115. In one embodiment, the heat sink 135 is positioned axially on the cooling channel 125 by means of a hydraulic press.

The position of the heat sink 135 on the cooling channel 125 can be determined by a height of the bearing surface on the outer end 160 of the heat sink 135 in relation to a bearing surface of the cooling channel 125 on the carrier 140. The sum of this height and the height of the component 120 above the printed circuit board 115 should be at least the same as an axial distance between the bearing surface for the printed circuit board 115 on the carrier 140 and a bearing surface for the cooling channel 125 on the carrier 140. The desired axial position of the heat sink 135 on the cooling channel 125 can be calculated in this manner, before setting the position. In one embodiment, the TIM can be taken into account, which can be provided at a predetermined thickness between the heat sink and the outer end 160 of the heat sink 135. The thickness of the TIM should be such that it completely fills any space between the heat sink 135 and the component 120 after the module 110 has been placed on the cooling system 105, without further increasing the distance between the two elements.

The module 110 can be attached to the cooling system 105, or vice versa, in step 420, in order to obtain a system 100. The attachment can take place in the framework of the method 400, or it can first take place at a later time. A specific module 110 is preferably assigned to a specific cooling system 105 before they are attached to one another. Both elements can be produced separately, and then first attached to one another after the cooling system 105 has been installed in the vehicle.

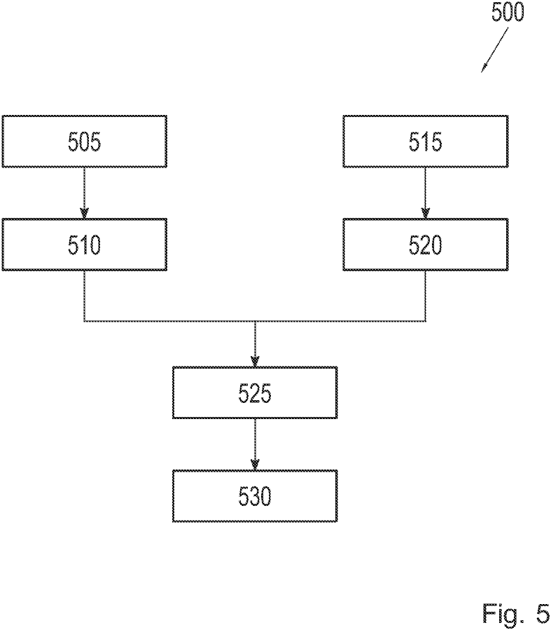

FIG. 5 shows a flow chart for a second method 500. A printed circuit board 115 can be populated in step 505, as described above in reference to step 405 in the method 400. The height of the component 120 in relation to the printed circuit board 115 can be determined in step 510, as described above in reference to step 410 of the method 400.

A heat sink 135 can be placed on a cooling channel 125 in step 515 at this time. The axial position of the heat sink 135 can be controlled in an arbitrary or nonarbitrary manner, which preferably corresponds to the variations of the axial position of the component 120 in relation to the printed circuit board 115.

Modules 110 can be assigned to cooling systems 105 in step 525. The heights determined in steps 510 and 520 can be brought into the relationships specified above for this. The assignment of a cooling system 105 to a module 110 can also be referred to as a pairing.

If a module 110 on a system 100 that has a cooling system 105 needs to be replaced, a module 110 can be selected in which the height of the component 120 above the printed circuit board 115 is as close as possible to that of the module 110 that is to be replaced. The height of the component 120 on the printed circuit board 115 can be indicated on the module 110. A height of a heat sink 135 on the cooling channel 125 can also be indicated in a similar manner on a cooling system 105. These labels can be numerical, alphanumerical, or encoded, i.e. in the form of a barcode or QR code.

### Reference Symbols

100 system
105 cooling system
110 module
115 printed circuit board
120 electronic component
125 cooling channel
130 cavity
135 heat sink
140 carrier
145 connection
150 longitudinal axis
155 inner end
160 outer end
165 seal
170 groove
205 recess
210 spacer
215 projection
220 section
305 male contact
310 cover
400 first method
405 population of printed circuit board
410 determination of the height of the component
415 axial positioning of the heat sink
420 attachment of module to the cooling system
500 second method
505 population of printed circuit board
510 determination of the height of the component
515 fitting of heat sink
520 determination of the height of the heat sink
525 pairing
530 placement of cooling system on the module

1. A cooling system comprising:
a heat sink for an electronic component on a printed circuit board; and
a cooling channel for a coolant,
wherein the cooling channel has a cavity for the heat sink , and
wherein the heat sink is designed to be placed in the cavity based on a distance between the component and the printed circuit board such that the printed circuit board can be attached to the cooling channel at a predetermined spacing, and such that the component bears on the heat sink .

2. The cooling system according to claim 1, wherein the heat sink is designed to be received in the cavity in a force-fitting manner.

3. The cooling system according to claim 2, wherein the heat sink is designed to be pressed, shrink-fitted, or thermally expanded into the cavity.

4. The cooling system according to claim 1, wherein the heat sink has an outer end that bears on the electronic component, and an inner end around which coolant in the cooling channel flows.

5. The cooling system according to claim 4, wherein the heat sink has a groove between its inner and outer ends in which a seal is placed in order to obtain a fluid-tight connection between the heat sink and the cooling channel in the radial direction.

6. The cooling system according to claim 5, wherein the seal is formed by an O-ring.

7. The cooling system according to claim 1, wherein the heat sink is placed in the cavity in the cooling channel and a label is attached indicating the position of the heat sink on the cooling system.

8. A heat sink with an outer end and an inner end, wherein the outer end bears on an electronic component placed on a printed circuit board, wherein coolant in a cooling channel flows around the inner end, wherein the heat sink is designed to be placed in a cavity in the cooling channel on the basis of a distance between the component and the printed circuit board, such that the printed circuit board can be placed on the cooling channel at a predetermined spacing thereto.

9. The heat sink according to claim 8, wherein a plurality of projections are formed on the inner end, which extend parallel to one another.

10. (canceled)

11. A method for obtaining a cooling system comprising a heat sink and a cooling channel through which coolant flows, wherein the cooling channel has a cavity for the heat sink , wherein the heat sink has an inner end and an outer end , wherein the outer end bears on an electronic component on a printed circuit board, wherein the coolant in the cooling channel flows around the inner end, wherein the method comprises the following steps:
determining a spacing at which the electronic component is placed on the printed circuit board m; and
positioning the heat sink in the cavity in the cooling channel based on this spacing, such that the outer end of the heat sink bears on the electronic component when the printed circuit board is placed on the cooling channel at a predetermined spacing thereto.

12. (canceled)
